(19) United States
(12) Patent Application Publication
(10) Pub. No.: US 2026/0179850 A1
(43) Pub. Date: Jun. 25, 2026

(54) MULTILAYER ELECTRONIC COMPONENT

(71) Applicant: SAMSUNG ELECTRO-MECHANICS CO., LTD., Suwon-si (KR)

(72) Inventors: Jung Won PARK, Suwon-si (KR); Yoo Jeong LEE, Suwon-si (KR); So Jung AN, Suwon-si (KR); So Eun CHOI, Suwon-si (KR); Chae Min PARK, Suwon-si (KR); Jong Ho LEE, Suwon-si (KR)

(73) Assignee: SAMSUNG ELECTRO-MECHANICS CO., LTD., Suwon-si (KR)

(21) Appl. No.: 19/374,188

(22) Filed: Oct. 30, 2025

(30) Foreign Application Priority Data
Dec. 24, 2024 (KR) 10-2024-0195095

(51) Int. Cl. H01G 4/232; H01G 4/008; H01G 4/012; H01G 4/12; H01G 4/30

(52) U.S. Cl. CPC H01G 4/2325; H01G 4/008; H01G 4/012; H01G 4/12; H01G 4/30

(57) ABSTRACT

A multilayer electronic component includes a body including a dielectric layer and an internal electrode alternately disposed with the dielectric layer in a first direction, the body including a first surface and a second surface opposing each other in the first direction, a third surface and a fourth surface opposing each other in a second direction, perpendicular to the first direction, and a fifth surface and a sixth surface opposing each other in a third direction, perpendicular to the first direction and the second direction, a metal layer disposed on an edge of the body, a first external electrode disposed on the third surface, and a second external electrode disposed on the fourth surface. The metal layer includes nickel (Ni) and further includes at least one of phosphorus (P) or boron (B).

### CROSS-REFERENCE TO RELATED APPLICATION(S)

This application claims benefit of priority to Korean Patent Application No. 10-2024-0195095 filed on Dec. 24, 2024 in the Korean Intellectual Property Office, the disclosure of which is incorporated herein by reference in its entirety.

### TECHNICAL FIELD

The present disclosure relates to a multilayer electronic component.

Multilayer ceramic capacitors (MLCCs), multilayer electronic components, are chip-shaped capacitors mounted on the printed circuit boards of various types of electronic products, such as video display devices such as liquid crystal displays (LCDs) and plasma display panels (PDPs), computers, smartphones and mobile phones, and onboard chargers (OBCs) and DC-DC converters for electric vehicles, to charge or discharge electricity.

Examples of methods for improving the moisture resistance reliability of multilayer ceramic capacitors include methods for forming external electrodes densely or forming external electrodes thickly. However, methods for forming external electrodes densely may have limitations, in that it may be difficult to improve the density of external electrodes when miniaturizing multilayer ceramic capacitors, and forming external electrodes thickly may cause problems in securing sufficient capacitance per unit volume, as the proportion of external electrodes in the entire component increases.

In detail, when forming the base electrode layer of the external electrode of the multilayer ceramic capacitor by applying and firing a conductive paste, the thickness of the base electrode layer applied to the edge of the body becomes thin, which may cause chipping due to a subsequent plating process, and thus causing a problem of reduced sealing of the multilayer ceramic capacitor.

Meanwhile, depending on the use of the multilayer ceramic capacitor, there are cases where a ground electrode is formed in addition to the terminal electrode. In this case, since a separate process of applying and firing a conductive paste is performed, a problem of performing an additional process may occur, and the problem of reduced sealing of the multilayer ceramic capacitor described above may occur in the process of forming the ground electrode at the edge of the body.

Therefore, there is a need for structural improvement that may easily obtaining miniaturization and high capacitance of multilayer ceramic capacitors while improving sealing properties.

### SUMMARY

An aspect of the present disclosure is to provide a multilayer electronic component in which a problem of reduced sealing properties of a multilayer electronic component due to an area in which an external electrode is thinly applied may be alleviated.

An aspect of the present disclosure is to alleviate a difficulty in forming a uniform base electrode layer when forming the base electrode layer of an external electrode by firing using a conductive paste.

An aspect of the present disclosure is to alleviate a problem of reduced sealing properties that may occur when forming a ground electrode in a multilayer electronic component.

An aspect of the present disclosure is to resolve a problem of having to additionally perform a process of applying a conductive paste when forming a ground electrode in a multilayer electronic component.

According to an aspect of the present disclosure, a multilayer electronic component includes a body including a dielectric layer and internal electrodes alternately disposed with the dielectric layer in a first direction, the body including a first surface and a second surface opposing each other in the first direction, a third surface and a fourth surface opposing each other in a second direction that is perpendicular to the first direction, and a fifth surface and a sixth surface opposing each other in a third direction that is perpendicular to the first direction and the second direction; a metal layer disposed on an edge connecting the first surface and the fifth surface, an edge connecting the first surface and the sixth surface, an edge connecting the second surface and the fifth surface, and an edge connecting the second surface and the sixth surface; a first external electrode disposed on the third surface; and a second external electrode disposed on the fourth surface. The metal layer includes nickel (Ni) and at least one selected from the group consisting of phosphorus (P) or boron (B).

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 schematically illustrates a perspective view of a multilayer electronic component according to an embodiment;

FIG. 2 schematically illustrates a cross-sectional view taken along line I-I′ of FIG. 1;

FIG. 3 schematically illustrates a cross-sectional view taken along line II-II′ of FIG. 1;

FIG. 4 schematically illustrates an enlarged view of region P of FIG. 3;

FIG. 5 schematically illustrates a cross-sectional view taken along line III-III′ of FIG. 1;

FIG. 6 schematically illustrates a cross-sectional view taken along line IV-IV′ of FIG. 1;

FIG. 7 schematically illustrates a perspective view of a body according to an embodiment;

FIG. 8 is a schematic perspective view of a body with a metal layer formed thereon according to an embodiment;

FIG. 9 schematically illustrates an exploded perspective view of a body according to an embodiment;

FIG. 10 schematically illustrates a perspective view of a multilayer electronic component according to an embodiment;

FIG. 11 schematically illustrates a perspective view of a body according to an embodiment;

FIG. 12 is a schematic perspective view of a body with a metal layer formed thereon according to an embodiment; and

FIG. 13 is a schematic perspective view of an exploded view of a body according to an embodiment.

### DETAILED DESCRIPTION

Hereinafter, embodiments will be described with reference to detailed embodiments and the attached drawings. However, the embodiments may be modified in various other forms, and the scope of the present disclosure is not limited to the embodiments described below. In addition, the embodiments are provided to more completely explain the present disclosure to those skilled in the art. Therefore, the shapes and sizes of elements in the drawings may be exaggerated for clearer explanation, and elements indicated by the same symbols in the drawings are the same elements.

In addition, to clearly explain the present disclosure in the drawings, parts that are not related to the explanation are omitted, and the size and thickness of each component illustrated in the drawings are arbitrarily indicated for the convenience of explanation, so the present disclosure is not necessarily limited to what is illustrated. In addition, components with the same functions within the scope of the same idea are described using the same reference symbols. Furthermore, throughout the specification, when a part is said to “include” a component, this does not mean excluding other components, but rather including other components, unless otherwise specifically stated.

In the drawings, the first direction may be defined as the stacking direction or the thickness direction, the second direction as the longitudinal direction, and the third direction as the width direction.

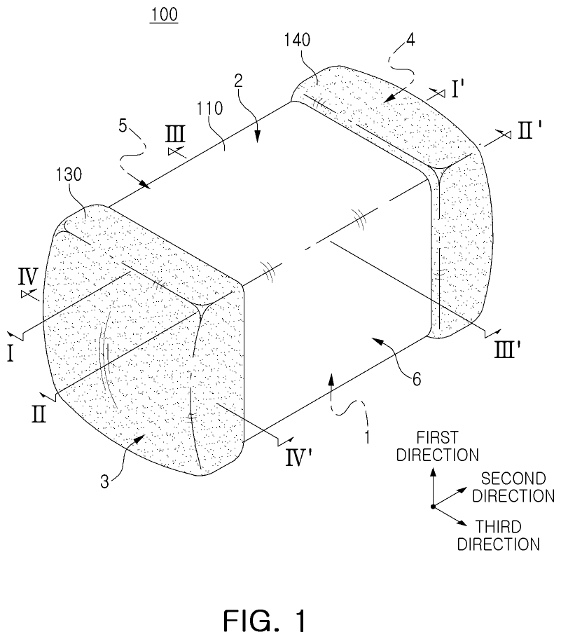

FIG. 1 schematically illustrates a perspective view of a multilayer electronic component according to an embodiment.

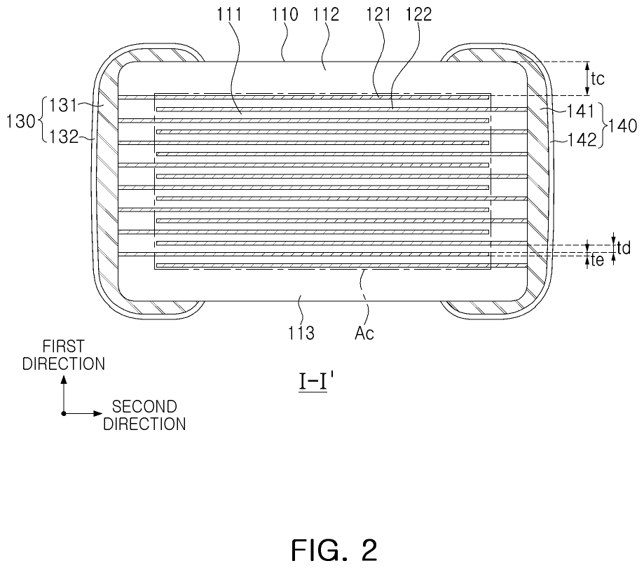

FIG. 2 schematically illustrates a cross-sectional view taken along line I-I′ of FIG. 1.

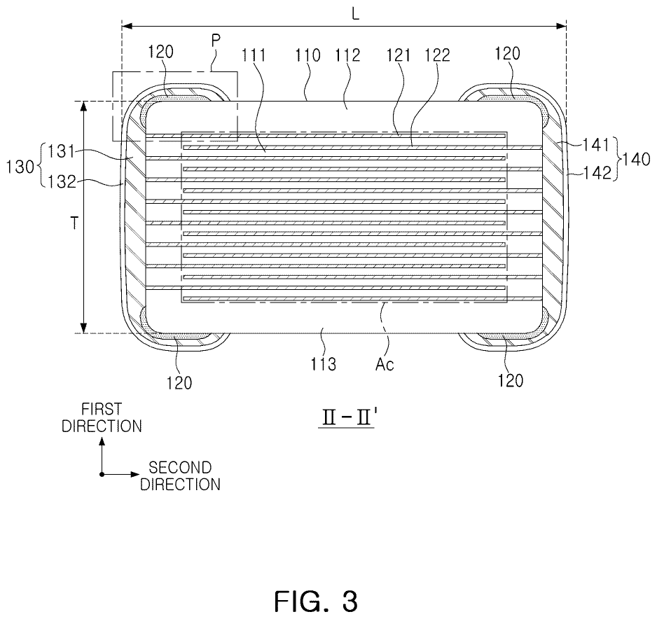

FIG. 3 schematically illustrates a cross-sectional view taken along line II-II′ of FIG. 1.

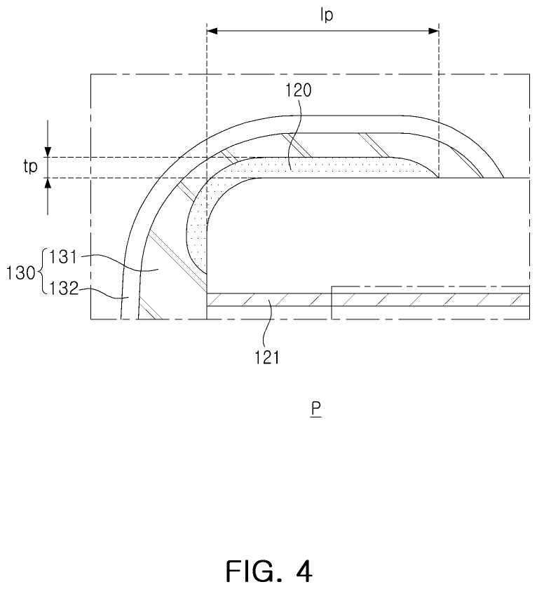

FIG. 4 schematically illustrates an enlarged view of region P of FIG. 3.

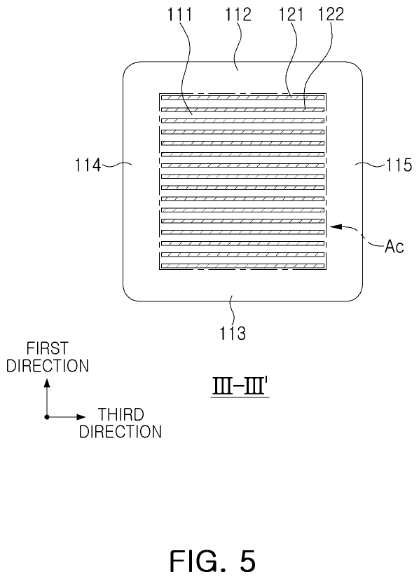

FIG. 5 schematically illustrates a cross-sectional view taken along line III-III′ of FIG. 1.

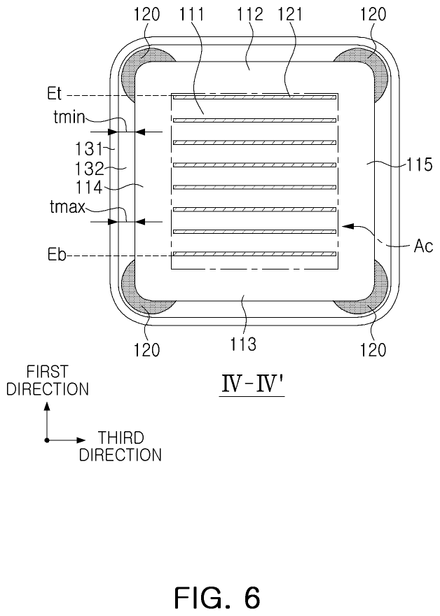

FIG. 6 schematically illustrates a cross-sectional view taken along line IV-IV′ of FIG. 1.

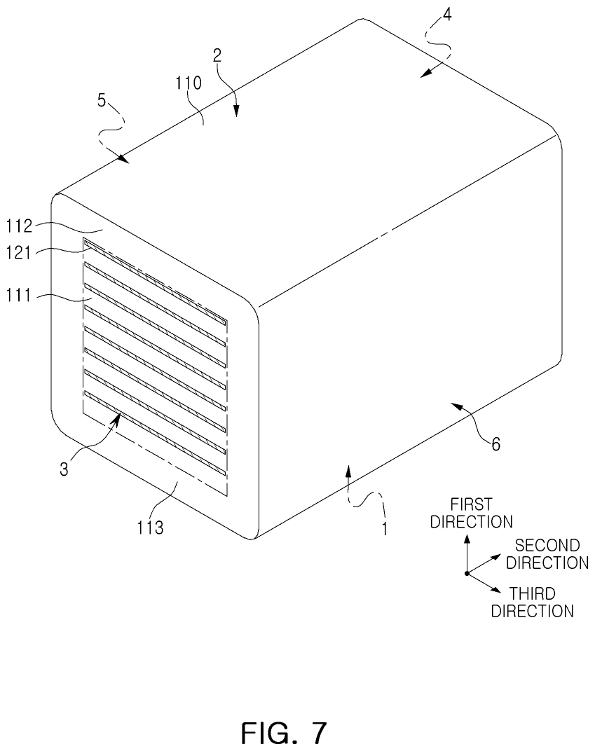

FIG. 7 schematically illustrates a perspective view of a body according to an embodiment.

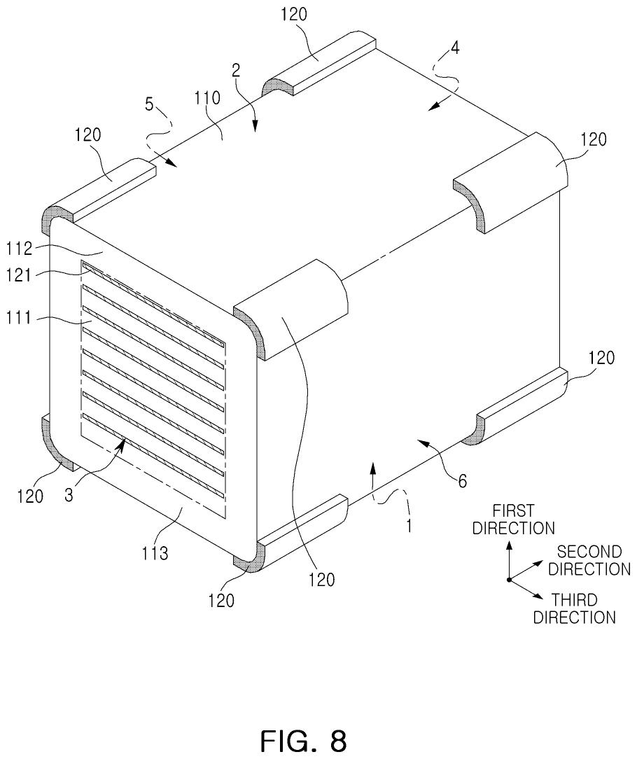

FIG. 8 schematically illustrates a perspective view of a body on which a metal layer is formed according to an embodiment.

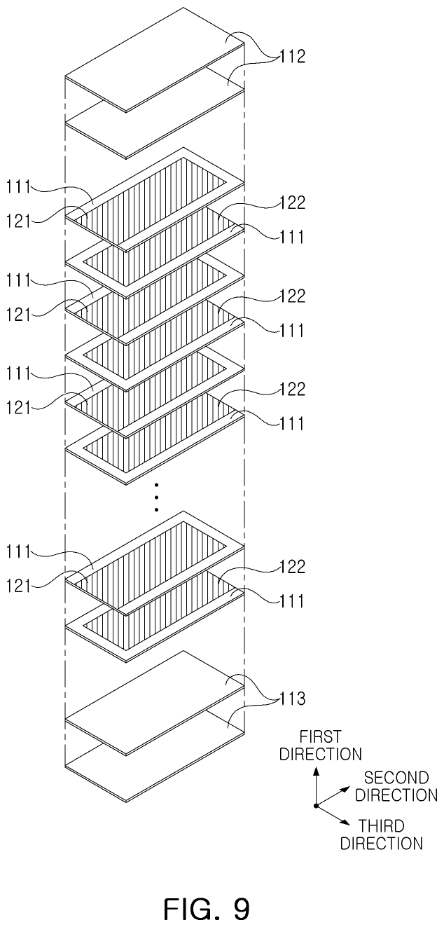

FIG. 9 schematically illustrates an exploded perspective view of a body according to an embodiment.

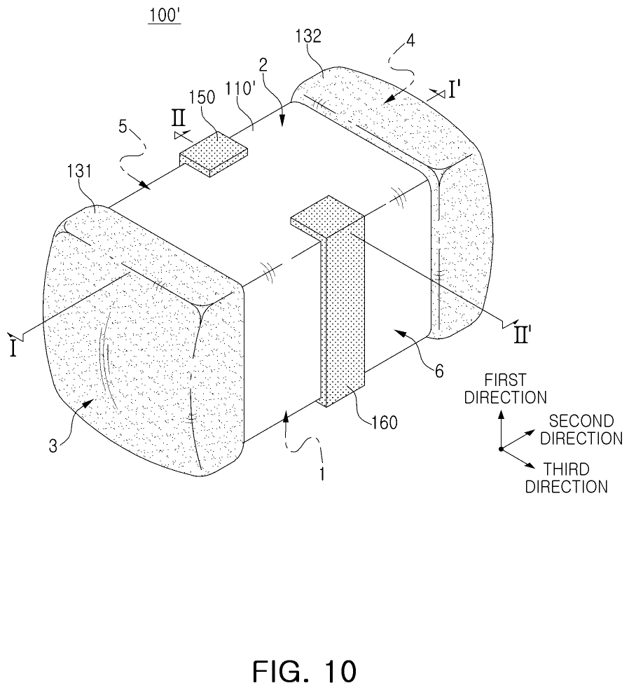

FIG. 10 schematically illustrates a perspective view of a multilayer electronic component according to an embodiment.

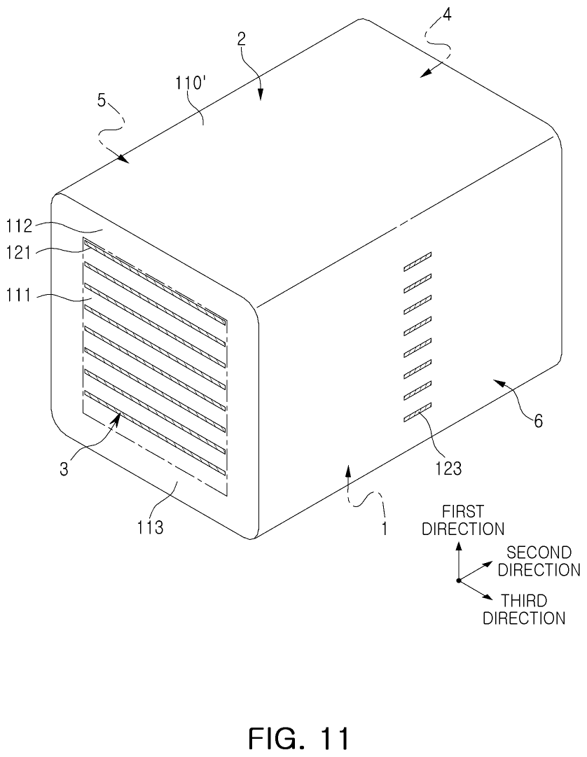

FIG. 11 schematically illustrates a perspective view of a body according to an embodiment.

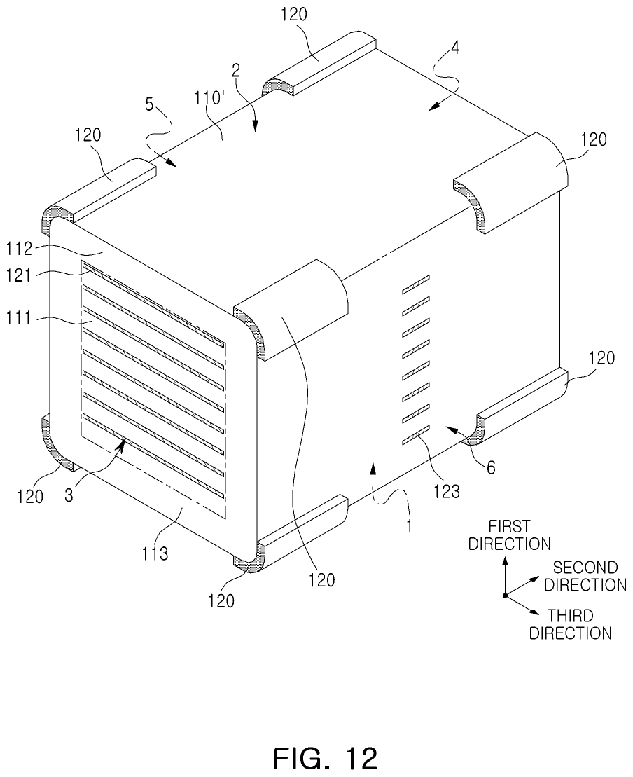

FIG. 12 is a perspective view schematically illustrating a state in which a metal layer is formed on a body according to an embodiment.

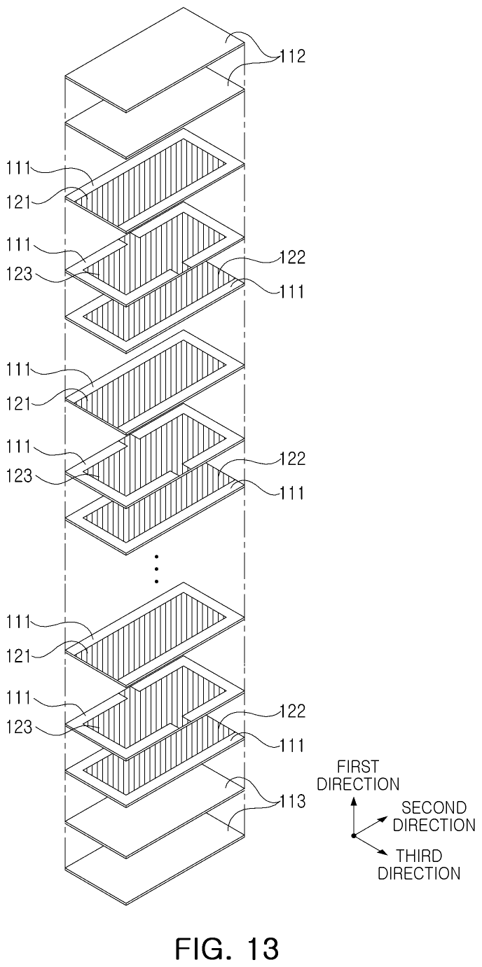

FIG. 13 is a perspective view schematically illustrating an exploded view of a body according to an embodiment.

Hereinafter, with reference to FIG. 1 to 13, a multilayer electronic component 100 according to an embodiment and various embodiments thereof will be described in detail.

A multilayer electronic component 100 according to an embodiment may include a body 110 that includes a dielectric layer 111 and internal electrodes 121 and 122 alternately disposed with the dielectric layer in a first direction, and that has a first surface 1 and a second surface 2 opposing each other in the first direction, a third surface 3 and a fourth surface 4 opposing each other in a second direction perpendicular to the first direction, and a fifth surface 5 and a sixth surface 6 opposing each other in a third direction perpendicular to the first direction and the second direction; a metal layer 120 disposed on an edge connecting the first surface and the fifth surface, an edge connecting the first surface and the sixth surface, an edge connecting the second surface and the fifth surface, and an edge connecting the second surface and the sixth surface; a first external electrode 130 disposed on the third surface; and a second external electrode 140 disposed on the fourth surface. The metal layer includes nickel (Ni) and may further include at least one of phosphorus (P) or boron (B).

The body 110 may include a dielectric layer 111 and internal electrodes 121 and 122, and the dielectric layer 111 and the internal electrodes 121 and 122 may be alternately disposed in a first direction. For example, in the present disclosure, the first direction may refer to a stacking direction of the dielectric layer 111 and the internal electrodes 121 and 122.

There is no particular limitation on the detailed shape of the body 110, but as illustrated in FIG. 7, the body 110 may be formed in a hexahedral shape or a similar shape. Due to shrinkage of the ceramic powder included in the body 110 during the firing process, the body 110 may not have a hexahedral shape with perfect straight lines, but may have a substantially hexahedral shape.

The body 110 may have first and second surfaces 1 and 2 opposing each other in a first direction, third and fourth surfaces 3 and 4 connected to the first and second surfaces 1 and 2 and opposing each other in a second direction that is perpendicular to the first direction, and fifth and sixth surfaces 5 and 6 connected to the first and second surfaces 1 and 2, connected to the third and fourth surfaces 3 and 4, and opposing each other in a third direction that is perpendicular to the first and second directions.

Meanwhile, since margin areas in which the internal electrodes 121 and 122 are not disposed on the dielectric layers 111 overlap each other, a step is generated due to the thickness of the internal electrodes 121 and 122, and an edge connecting the first surface and the third to sixth surfaces and/or an edge connecting the second surface and the third to sixth surfaces may have a shape that is contracted toward the center of the body 110 in the first direction of the body 110 when viewed from the first surface or the second surface. Alternatively, due to contraction behavior during the sintering process of the body, an edge connecting the first surface 1 and the third to sixth surfaces 3, 4, 5 and 6 and/or an edge connecting the second surface 2 and the third to sixth surfaces 3, 4, 5 and 6 may have a shape that is contracted toward the center of the body 110 in the first direction of the body 110 when viewed from the first surface or the second surface. Alternatively, to prevent chipping defects or the like, edges connecting respective surfaces of the body 110 may be rounded by performing a separate process, so that the edges connecting the first surface and the third to sixth surfaces and/or the edges connecting the second surface and the third to sixth surfaces may have a round shape.

The plurality of dielectric layers 111 forming the body 110 are in a fired state, and the boundary between adjacent dielectric layers 111 may be integrated to the extent that it is difficult to confirm without using a scanning electron microscope (SEM). The number of stacks of dielectric layers need not be particularly limited, and may be determined in consideration of the size of the multilayer electronic component. For example, the body may be formed by stacking 400 or more dielectric layers.

The dielectric layer 111 may be formed by manufacturing a ceramic slurry containing ceramic powder, an organic solvent, and a binder, applying and drying the slurry on a carrier film to prepare a ceramic green sheet, and then firing the ceramic green sheet. The ceramic powder is not particularly limited as long as it may obtain sufficient electrostatic capacitance, but, for example, barium titanate-based (BaTiO₃) powder may be used as the ceramic powder. For a more detailed example, the barium titanate (BaTiO₃) powder maybe at least one of BaTiO₃, (Ba₁₋ₓCaₓ)TiO₃ (0<x<1), Ba(Ti_{1-y}Ca_{y})O₃ (0<y<1), (Ba₁₋ₓCaₓ)(Ti_{1-y}Zr_{y})O₃ (0<x<1, 0<y<1), and Ba(Ti_{1-y}Zr_{y})O₃ (0<y<1), and the CaZrO₃-based paraelectric powder may be (Ca₁₋ₓSrₓ)(Zr_{1-y}Ti_{y})O₃ (0<x<1, 0<y<1).

The average thickness (td) of the dielectric layer 111 is not particularly limited.

To miniaturize and increase the capacitance of the multilayer electronic component 100, the average thickness (td) of the dielectric layer 111 may be 0.35 μm or less, and to improve the reliability of the multilayer electronic component 100 under high temperature and high pressure, the average thickness (td) of the dielectric layer 111 may be 3 μm or more.

The average thickness (td) of the dielectric layer 111 may refer to the average thickness of at least one dielectric layer among a plurality of dielectric layers.

The average thickness (td) of the dielectric layer 111 may be measured by scanning an image of the first and second direction cross section (L-T cross section) of the body 110 using a scanning electron microscope (SEM). For example, the average thickness (td) of the dielectric layer 111 may be a value obtained by scanning and obtaining an image of the first and second direction (L-T) cross-section cut from the center of the width direction of the body 110 using a scanning electron microscope (SEM), and averaging the thicknesses measured at a ¼ points, a 2/4 point, and a ¾ point, provided by dividing the dielectric layer into four parts in the longitudinal direction, based on the dielectric layer of one layer adjacent to the point at which the longitudinal center line and the thickness direction center line of the capacitance forming portion meet in the obtained image. If this measurement is extended to the upper two and lower two dielectric layers having equal intervals based on the dielectric layer of one layer adjacent to the point at which the longitudinal center line and the thickness direction center line of the capacitance forming portion meet, the average thickness of the dielectric layer may be further generalized.

The body 110 may include a capacitance forming portion (Ac) which is disposed inside the body 110 and in which a capacitance is formed by including a first internal electrode 121 and a second internal electrode 122 that are alternately disposed with a dielectric layer 111, and cover portions 112 and 113 formed above and below the capacitance forming portion (Ac) in the first direction.

The capacitance forming portion (Ac) is a portion that contributes to the formation of the capacitance of the capacitor, and may be formed by repeatedly stacking a plurality of first and second internal electrodes 121 and 122 with a dielectric layer 111 therebetween, and may refer to an area in which the first and second internal electrodes 121 and 122 overlap in the first direction. In addition, the first internal electrode 121 may be disposed at the top end of the capacitance forming portion (Ac) in the first direction, and the second internal electrode 122 may be disposed at the bottom end thereof in the first direction.

The internal electrodes 121 and 122 may include first and second internal electrodes 121 and 122. The first and second internal electrodes 121 and 122 may be alternately disposed with the dielectric layer 111 forming the body 110 and interposed therebetween, to face each other, and may be exposed to the third and fourth surfaces 3 and 4 of the body 110, respectively. For example, in an embodiment, the first internal electrode 121 may have one end in the second direction in contact with the third surface 3, and the second internal electrode 122 may have one end in the second direction in contact with the fourth surface 4.

Referring to FIG. 2, the first internal electrode 121 may be connected to the first external electrode 130, and the second internal electrode 122 may be connected to the second external electrode 140.

The first internal electrode 121 may be connected to the first external electrode 130 without being connected to the second external electrode 140, and the second internal electrode 122 may be connected to the second external electrode 140 without being connected to the first external electrode 130. For example, the first internal electrode 121 may be formed at a certain distance from the fourth surface 4, and the second internal electrode 122 may be formed at a certain distance from the third surface 3. In addition, the first and second internal electrodes 121 and 122 may be disposed at a certain distance from the fifth and sixth surfaces of the body 110.

The conductive metal included in the internal electrodes 121 and 122 may be at least one of Ni, Cu, Pd, Ag, Au, Pt, In, Sn, Al, Ti, and alloys thereof, and the present disclosure is not limited thereto.

The average thickness (te) of the internal electrodes 121 and 122 is not particularly limited and may vary depending on the purpose. To miniaturize the multilayer electronic component 100, the average thickness (te) of the internal electrodes 121 and 122 may be 0.35 μm or less, and to improve the reliability of the multilayer electronic component 100 under high temperature and high pressure, the average thickness (te) of the internal electrodes 121 and 122 may be 3 μm or more.

The average thickness (te) of the internal electrodes 121 and 122 may refer to the average thickness of at least one or more internal electrodes among a plurality of internal electrodes.

The average thickness (te) of the internal electrodes 121 and 122 may be measured by scanning the image of the first and second direction cross-section (L-T cross-section) of the body 110 using a scanning electron microscope (SEM). For example, the average thickness (te) of the internal electrodes 121 and 122 may be a value obtained by averaging the thicknesses measured at a ¼ point, a 2/4 point, and a ¾ point when dividing the internal electrode into four parts in the longitudinal direction, based on the internal electrode of one layer adjacent to the point at which the longitudinal center line and the thickness direction center line of the capacitance forming portion of the internal electrode meet, in the image of the first and second direction (L-T) cross-section cut from the center of the width direction of the body 110 scanned using a scanning electron microscope (SEM). If this measurement is extended to the upper two and lower two internal electrodes having equal spacing based on the internal electrode of one layer adjacent to the point at which the longitudinal center line and the thickness direction center line of the capacitance forming portion meet, the average thickness of the internal electrode may be further generalized.

Referring to FIG. 9, the cover portions 112 and 113 may be disposed on the upper surface and lower surface of the capacitance forming portion (Ac) in the first direction.

The cover portions 112 and 113 may basically play a role in preventing damage to the internal electrode due to physical or chemical stress.

The cover portions 112 and 113 may include the same material as a material of the dielectric layer 111. For example, the cover portions 112 and 113 may include a ceramic material, for example, a barium titanate (BaTiO₃)-based ceramic material.

Meanwhile, the thickness of the cover portions 112 and 113 does not need to be particularly limited. For example, the thickness tc1 of the cover portions 112 and 113 may be 20 μm or less, respectively.

The average thickness tc1 of the cover portions 112 and 113 may refer to the size in the first direction, and may be an average value of the first direction size of the cover portions 112 and 113 measured at five equally spaced points above or below the capacitance forming portion (Ac).

Referring to FIG. 5, margin portions 114 and 115 may be disposed on the side surfaces of the capacitance forming portion (Ac).

The margin portions 114 and 115 may include a first margin portion 114 disposed on the fifth surface 5 of the body 110 and a second margin portion 115 disposed on the sixth surface 6. For example, the margin portions 114 and 115 may be disposed on both end surfaces of the ceramic body 110 in the width direction.

As illustrated in FIG. 5, the margin portions 114 and 115 may refer to areas between both ends of the first and second internal electrodes 121 and 122 and the boundary surface of the body 110 in a cross-section of the body 110 cut in the width-thickness (W-T) direction.

The margin portions 114 and 115 may basically play a role in preventing damage to the internal electrode due to physical or chemical stress.

The margin portions 114 and 115 may be formed by forming the internal electrode by applying a conductive paste except for the area in which the margin portion is to be formed on the ceramic green sheet.

Meanwhile, the width of the margin portions 114 and 115 need not be particularly limited. For example, the average width of the margin portions 114 and 115 may be 20 μm or less, respectively.

The average width of the margin portions 114 and 115 may refer to the average size of the area in the third direction, in which the internal electrode is spaced from the fifth surface, and the average size of the area in the third direction, in which the internal electrode is spaced from the sixth surface, and may be an average value of the third direction sizes of the margin portions 114 and 115 measured at five equally spaced points on the side surface of the capacitance forming portion (Ac).

The external electrodes 130 and 140 may be disposed on the body 110, and in detail, may be disposed on the third surface 3 and the fourth surface 4 of the body 110.

The external electrodes 130 and 140 may include a first external electrode 130 disposed on the third surface 3 of the body 110 and a second external electrode 140 disposed on the fourth surface 4 of the body 110.

Meanwhile, the external electrodes 130 and 140 need not be limited to being disposed only on the third surface 3 and the fourth surface 4 of the body. Referring to FIGS. 1 and 2, the first external electrode 130 may be disposed by extending from the third surface 3 of the body 110 to portions of the first, second, fifth, and sixth surfaces 1, 2, 5 and 6, and the second external electrode 140 may be disposed by extending from the fourth surface 4 to portions of the first, second, fifth, and sixth surfaces 1, 2, 5 and 6.

The external electrodes 130 and 140 may include electrode layers 131 and 141 disposed on the body 110 and connected to the internal electrodes 121 and 122.

In detail, the first external electrode 130 may include a first electrode layer 131 disposed on the body 110 and connected to the first internal electrode 121, and the second external electrode 140 may include a second electrode layer 141 disposed on the body 110 and connected to the second internal electrode 122.

The first and second electrode layers 131 and 141 may be connected to the internal electrodes 121 and 122, respectively, and may play a role in securing electrical connectivity between the external electrodes 130 and 140 and the internal electrodes 121 and 122.

The first electrode layer 131 and the second electrode layer 141 may include a conductive metal. A material having excellent electrical conductivity may be used as the conductive metal, and is not particularly limited. For example, the conductive metal may be at least one of nickel (Ni), copper (Cu), and alloys thereof.

For more detailed examples of the first and second electrode layers 131 and 141, the electrode layers may be sintered electrodes including a conductive metal and glass, or resin-based electrodes including a conductive metal and resin.

The first and second electrode layers 131 and 141 may be in the form of sintered electrodes and resin-based electrodes sequentially formed on the body. In addition, the electrode layers may be formed by transferring a sheet including a conductive metal onto the body, or may be formed by transferring a sheet including a conductive metal onto the sintered electrode.

The size of the multilayer electronic component 100 does not need to be particularly limited. For example, the length of the multilayer electronic component 100 may be 0.1 mm to 10.0 mm, the thickness of the multilayer electronic component 100 may be 0.1 mm to 10.0 mm, and the width of the multilayer electronic component 100 may be 0.1 mm to 10.0 mm.

In this case, the length of the multilayer electronic component 100 may refer to a maximum size of the multilayer electronic component 100 in the second direction, the thickness of the multilayer electronic component 100 may refer to a maximum size of the multilayer electronic component 100 in the first direction, and the width of the multilayer electronic component 100 may refer to a maximum size of the multilayer electronic component 100 in the third direction.

As described above, the body 110 may include an edge connecting the first surface 1 and the third to sixth surfaces 3, 4, 5 and 6 and/or an edge connecting the second surface and the third to sixth surfaces 3, 4, 5 and 6. The edges of the body 110 may become major penetration paths of external moisture or plating solution, and in detail, the edge connecting the first surface and the fifth surface, the edge connecting the first surface and the sixth surface, the edge connecting the second surface and the fifth surface, and the edge connecting the second surface and the sixth surface may become portions vulnerable to external moisture or plating solution as a result of the electrode layers 131 and 141 of the external electrodes 130 and 140 being formed thin. Accordingly, a problem may arise in which it is difficult to secure the sealing of the multilayer electronic component 100.

In the related art, there is an attempt to improve the sealing of the multilayer electronic component 100 by densely forming the external electrode on the edge of the body 110 or forming the thickness of the external electrode thick. However, the method of densely forming the external electrode may have limitations in that it is difficult to improve the density of the external electrode when miniaturizing the multilayer electronic component, and if the thickness of the external electrode is thick, the proportion of the external electrode in the entire component increases, which may cause a problem in that it is difficult to secure sufficient capacitance per unit volume.

Accordingly, in an embodiment, by disposing a metal layer on an edge connecting the first surface and the fifth surface, an edge connecting the first surface and the sixth surface, an edge connecting the second surface and the fifth surface, and an edge connecting the second surface and the sixth surface, the edge of the body 110 vulnerable to penetration of external moisture or plating solution is protected, and by forming an external electrodes 130 and 140 located on the edge of the body 110 with a sufficient thickness, the sealing of the multilayer electronic component 100 may be improved.

Meanwhile, since the edge of the body 110 may be formed of a ceramic material of the dielectric layer 111, when forming a metal layer formed of a single element, it may be difficult to secure sufficient bonding strength between the metal layer 120 and the body 110. In addition, when forming the metal layer 120 by applying a conductive paste containing a conductive metal, it may be difficult to form a uniform metal layer 120 on the edge of the body 110.

Therefore, in an embodiment of the present disclosure, the metal layer 120 includes nickel (Ni) and further includes at least one of phosphorus (P) or boron (B), thereby forming a thin and uniform metal layer 120 on the edge connecting the first surface and the fifth surface, the edge connecting the first surface and the sixth surface, the edge connecting the second surface and the fifth surface, and the edge connecting the second surface and the sixth surface, and securing sufficient bonding strength between the metal layer 120 and the body 110.

Since the metal layer 120 is formed at the edge of the body 110 which may be the main penetration path of external moisture or plating solution, when the metal layer 120 itself acts as a barrier against penetration of external moisture or plating solution, the moisture resistance reliability of the multilayer electronic component 100 may be further improved. In detail, the metal layer 120 may substantially not include a glass component which is a component vulnerable to the plating solution, and may substantially be composed only of metal. For example, the content of the metal element relative to the total elements included in the metal layer 120 may be 80 at % or more.

Referring to FIG. 8, the metal layer 120 may include a first metal layer of which one end in the second direction contacts the third surface 3, and a second metal layer of which one end in the second direction end contacts the fourth surface 4. At this time, the first metal layer and the second metal layer may be disposed while being spaced apart from each other in the second direction. Accordingly, electrical connection between the first metal layer and the second metal layer may be prevented.

Referring to FIGS. 3 and 4, the electrode layers 131 and 141 may be disposed to cover the metal layers 120. Accordingly, the effect of suppressing the penetration of external moisture or erosion from the plating solution may be further improved.

Referring to FIGS. 3 and 4, the second-direction length of the body 110 is represented as L, the first-direction thickness of the body 110 is represented as T, the second-direction length of the metal layer 120 is represented as lp, and the first-direction thickness of the metal layer 120 is represented as tp.

When lp/L is less than 0.05, the effect of the metal layer 120 covering the edge of the body 110 may not be sufficient. When lp/L exceeds 0.33, the external electrodes 130 and 140 formed on the metal layers 120 are excessively formed in the second direction, which makes it difficult to secure a sufficient gap between the external electrodes 130 and 140. Accordingly, in an embodiment, by satisfying lp/L of 0.05 or more and 0.33 or less, the metal layer 120 may sufficiently secure the effect of protecting the edge of the body 110 while simultaneously securing a sufficient gap between the external electrodes 130 and 140.

Referring to FIGS. 3, 4, and 7, the metal layer 120 may also be disposed on the edge connecting the first surface 1 and the third surface 3 and/or the fourth surface 4, and the edge connecting the second surface 2 and the third surface 3 and/or the fourth surface 4. For example, the metal layer 120 may be disposed by extending to a portion of the third surface 3 or the fourth surface 4. Accordingly, the sealing improvement effect of the multilayer electronic component 100 according to an embodiment of the present disclosure may be further improved. At this time, if tp/T exceeds 0.04, the thickness of the external electrodes 130 and 140 formed in an area other than the edge portion increases, so that the effect of improving the capacitance per unit volume of the multilayer electronic component 100 may be reduced. Accordingly, in an embodiment, by ensuring that tp/T satisfies 0.04 or less, the sealing of the multilayer electronic component 100 according to an embodiment may be secured while preventing the effect of improving the capacitance per unit volume of the multilayer electronic component 100 from being reduced.

Meanwhile, the lower limit value of tp/T is not particularly limited, and tp may be 1 um or more to form the metal layer 120 with a sufficient thickness.

The method of measuring L, lp, T, and tp is not particularly limited. Other methods and/or tools appreciated by one of ordinary skill in the art, even if not described in the present disclosure, may also be used. For example, L, lp, T, and tp may be measured using equipment such as an optical microscope (OM) or a scanning electron microscope (SEM) in a cross-section, such as the first and second-direction cross-section of the multilayer electronic component 100 polished to a point at which the metal layer 120 and the internal electrodes 121 and 122 are simultaneously exposed in the third direction, as illustrated in FIG. 3. At this time, L may represent the maximum size of the multilayer electronic component 100 in the second direction, T may represent the maximum size of the multilayer electronic component 100 in the first direction, lp may represent the second-direction length of the metal layer 120 between one end of the metal layer 120 in the second direction and the outermost end of the body 110 in the second direction, and tp may represent the first-direction maximum thickness of the metal layer 120 disposed on the surface of the body 110 that faces therewith in the first direction.

Referring to FIG. 6, the first electrode layer 131 may have a maximum thickness (tmax) and a minimum thickness (tmin) in a region between an extension line (Et) of the first internal electrode 121 located at the uppermost position in the first direction and an extension line (Eb) of the first internal electrode 121 located at the lowermost position in the first direction. In the case where the metal layer 120 is disposed on an edge connecting the first surface and the fifth surface, an edge connecting the first surface and the sixth surface, an edge connecting the second surface and the fifth surface, and an edge connecting the second surface and the sixth surface, as in an embodiment, the external electrodes 130 and 140 may be formed with a uniform thickness compared to the case where the metal layer 120 is not formed. In detail, in an embodiment, tmin/tmax may be 0.5 or more and 1 or less. Meanwhile, although FIG. 6 expresses the first electrode layer 131, the characteristics regarding the thickness deviation of the first electrode layer 131 may be similarly applied to the second electrode layer 141 of the second external electrode 140.

The method of measuring tmin and tmax is not particularly limited. Other methods and/or tools appreciated by one of ordinary skill in the art, even if not described in the present disclosure, may also be used. tmin and tmax may be measured using equipment such as an optical microscope (OM) or a scanning electron microscope (SEM) in a cross-section, such as the first and third-direction cross-section of the multilayer electronic component 100 polished so that the metal layer 120 and the first internal electrode 121 are simultaneously exposed in the second direction, as illustrated in FIG. 6. tmin and tmax may refer to the third-direction thickness of the first internal electrode 121 measured in the area between the extension line (Et) of the first internal electrode 121 located at the uppermost position in the first direction and the extension line (Eb) of the first internal electrode 121 located at the lowermost position in the first direction.

In an embodiment, the metal layer 120 may be disposed while being spaced apart from the internal electrodes 121 and 122. Accordingly, the external electrodes 130 and 140 formed in the area excluding the edge of the body 110 may be prevented from being formed excessively thick, thereby further enhancing the effect of improving the capacitance per unit volume of the multilayer electronic component 100.

Referring to FIG. 10, a multilayer electronic component 100′ according to an embodiment may further include a third external electrode 150 disposed on the fifth surface 5 of a body 110′, and a fourth external electrode 160 disposed on the sixth surface 6 of the body 110′.

The body 110′ according to an embodiment may include a first internal electrode 121 having one end in the second direction in contact with the third surface 3, a second internal electrode 122 having one end in the second direction in contact with the fourth surface 4, and a third internal electrode 123 having one end in the third direction in contact with the fifth surface 5 and the other end in the third direction in contact with the sixth surface, as illustrated in FIG. 13. The body 110′ according to an embodiment may include the same configurations as the body 100 according to the embodiment described above, except that it further includes the third internal electrode 123. For example, as illustrated in FIG. 12, a metal layer 120 may be disposed on an edge connecting the first surface and the fifth surface of the body 110′, an edge connecting the first surface and the sixth surface, an edge connecting the second surface and the fifth surface, and an edge connecting the second surface and the sixth surface.

Referring to FIG. 11, in the body 110′ according to an embodiment, one end of the first internal electrode 121 is in contact with the third surface 3, and although not directly illustrated in FIG. 11, the second internal electrode 122 may be in contact with the fourth surface 4, and the third internal electrode 123 may be in contact with the fifth surface 5 and the sixth surface 6. Meanwhile, in the present disclosure, a case in which each of the third internal electrodes 123 is in contact with the fifth surface 5 and the sixth surface 6 simultaneously, but is not limited thereto, and some of the third internal electrodes may be in contact with the fifth surface 5 and some thereof may be in contact with the sixth surface 6.

In an embodiment, the third external electrode 150 and the fifth external electrode 160 may include nickel (Ni) and may further include at least one of phosphorus (P) or boron (B). Accordingly, the problem of reduced sealing that may occur when forming a ground electrode in a multilayer electronic component may be alleviated, and the problem of having to additionally perform a process of applying a conductive paste may be prevented.

In an embodiment, the metal layer 120 may be formed by an electroless plating method. Accordingly, a uniform and dense metal layer 120 may be formed on the edge of the body 110 without a metal component.

The method of controlling the formation length, thickness, and application area of the metal layer 120 is not particularly limited. For example, when forming the metal layer 120 by electroless nickel (Ni) plating, after the body 110 is sintered, degreasing and pretreatment are performed, and then a method of applying a catalytic particle such as palladium (Pd) or the like, or other seed layers to the area in which the metal layer 120 is to be formed, immersing the same in a solution containing Ni ions, and then reducing the Ni ions may be used.

In an embodiment, the third external electrode 150 and the fourth external electrode 160 may be formed by electroless plating. Accordingly, the third external electrode 150 and the fourth external electrode 160 may be uniformly and densely formed on the edge of the body 110′ and the first surface 1 and the second surface 2 of the body 110′.

Meanwhile, the third external electrode 150 and the fourth external electrode 160 may be formed by the same electroless plating method as the metal layer 120, but are not limited thereto.

As set forth above, according to an embodiment, there is provided a multilayer electronic component in which a problem of reduced sealing properties of a multilayer electronic component due to an area in which an external electrode is thinly applied may be alleviated.

According to an embodiment, a difficulty in forming a uniform base electrode layer when forming the base electrode layer of an external electrode by firing using a conductive paste may be alleviated.

According to an embodiment, a problem of reduced sealing properties that may occur when forming a ground electrode in a multilayer electronic component may be alleviated.

According to an embodiment, a problem of having to additionally perform a process of applying a conductive paste when forming a ground electrode in a multilayer electronic component may be resolved.

Although the embodiments of the present disclosure have been described in detail above, the present disclosure is not limited by the above-described embodiments and the attached drawings, but is intended to be limited by the appended claims. Accordingly, various forms of substitution, modification, and change may be made by those skilled in the art within the scope that does not depart from the technical idea of the present disclosure described in the claims, and this also falls within the scope of the present disclosure.

In addition, the expression ‘an(one) embodiment’ used in the present disclosure does not mean the same embodiment, and is provided to emphasize and explain each unique feature that is different from the other. However, the embodiments presented above do not exclude being implemented in combination with the features of another embodiment. For example, even if a matter described in a specific embodiment is not described in another embodiment, it can be understood as a description related to another embodiment, unless there is a description that is contrary or contradictory to that matter in another embodiment.

The terms used in the present disclosure are used only to describe one embodiment, and are not intended to limit the present disclosure. In this case, the singular expression includes the plural expression unless the context clearly indicates otherwise.

While example embodiments have been illustrated and described above, it will be apparent to those skilled in the art that modifications and variations could be made without departing from the scope of the present disclosure as defined by the appended claims.

What is claimed is:

1. A multilayer electronic component comprising:
a body including a dielectric layer and internal electrodes alternately disposed with the dielectric layer in a first direction, the body including a first surface and a second surface opposing each other in the first direction, a third surface and a fourth surface opposing each other in a second direction that is perpendicular to the first direction, and a fifth surface and a sixth surface opposing each other in a third direction that is perpendicular to the first direction and the second direction;
a metal layer disposed on an edge connecting the first surface and the fifth surface, an edge connecting the first surface and the sixth surface, an edge connecting the second surface and the fifth surface, and an edge connecting the second surface and the sixth surface;
a first external electrode disposed on the third surface; and
a second external electrode disposed on the fourth surface,
wherein the metal layer includes nickel (Ni) and at least one selected from the group consisting of phosphorus (P) or boron (B).

2. The multilayer electronic component of claim 1, wherein the internal electrodes include a first internal electrode having one end in the second direction in contact with the third surface, and a second internal electrode having one end in the second direction in contact with the fourth surface.

3. The multilayer electronic component of claim 1, wherein the metal layer includes a first metal layer having one end in the second direction in contact with the third surface, and a second metal layer spaced apart from the first metal layer in the second direction and having one end in the second direction in contact with the fourth surface.

4. The multilayer electronic component of claim 1, wherein, when a length of the body in the second direction is L and a length of the metal layer in the second direction is lp, lp/L satisfies 0.05 or more and 0.33 or less.

5. The multilayer electronic component of claim 1, wherein, when a thickness of the body in the first direction is T and a thickness of the metal layer in the first direction is tp, tp/T satisfies 0.04 or less.

6. The multilayer electronic component of claim 1, wherein the first external electrode includes a first electrode layer in contact with the third surface, and a first plating layer disposed on the first electrode layer, and the second external electrode includes a second electrode layer in contact with the fourth surface, and a second plating layer disposed on the second electrode layer,
wherein the first electrode layer and the second electrode layer cover the metal layer.

7. The multilayer electronic component of claim 1, wherein the first external electrode includes a first electrode layer in contact with the third surface, and a first plating layer disposed on the first electrode layer, and the second external electrode includes a second electrode layer in contact with the fourth surface, and a second plating layer disposed on the second electrode layer,
wherein, when a maximum thickness of the first electrode layer or the second electrode layer is tmax and a minimum thickness of the first electrode layer or the second electrode layer is tmin, tmin/tmax is 0.5 or more and 1.0 or less.

8. The multilayer electronic component of claim 1, wherein the metal layer extends to a portion of the third surface or the fourth surface.

9. The multilayer electronic component of claim 1, wherein the metal layer is spaced apart from the internal electrodes.

10. The multilayer electronic component of claim 1, further comprising a third external electrode disposed on the fifth surface and a fourth external electrode disposed on the sixth surface.

11. The multilayer electronic component of claim 10, wherein the internal electrodes include a first internal electrode having one end in the second direction in contact with the third surface, a second internal electrode having one end in the second direction in contact with the fourth surface, and a third internal electrode having a first end in the third direction in contact with the fifth surface and a second end in the third direction in contact with the sixth surface.

12. The multilayer electronic component of claim 10, wherein the third external electrode and the fourth external electrode include nickel (Ni) and at least one selected from the group consisting of phosphorus (P) or boron (B).

13. The multilayer electronic component of claim 10, wherein the third external electrode and the fourth external electrode are electroless plated layers.

14. The multilayer electronic component of claim 1, wherein the metal layer is an electroless plated layer.

15. The multilayer electronic component of claim 11, wherein the third electrode is disposed between the first internal electrode and the second internal electrode.

16. The multilayer electronic component of claim 2, wherein a portion of the metal layer overlaps the first internal electrode and the second internal electrode.
